(19) United States
(12) Patent Application Publication
(10) Pub. No.: US 2005/0266611 A1
(43) Pub. Date: Dec. 1, 2005

(54) Flip chip packaging method and flip chip assembly thereof

(76) Inventors: Jack Tu, Taichung County (TW); Hsiu-Fen Ho, Taichung City (TW)

Correspondence Address: BIRCH STEWART KOLASCH & BIRCH, PO BOX 747, FALLS CHURCH, VA, 22040-0747, US

(21) Appl. No.: 10/856,949

(22) Filed: Jun. 1, 2004

(51) Int. Cl. H01L 21/44; H01L 23/495

(52) U.S. Cl. 438/108; 438/123; 438/127; 257/673

(57) ABSTRACT

The present invention discloses a semi-etching method, which comprises the steps of etching a flip chip bump when producing a lead frame for packaging; electroplating a metal such as gold, silver, or solder onto the flip chip bump by an electroplating process; electrically connecting the bond pad of a chip and the flip chip bump; and injecting a packaging material for the packaging. The manufacturing process of the invention does not need to grow flip chip bumps (or solder balls) on the bond pad, but only uses the original manufacturing equipments for producing the lead frame. Therefore, the invention can greatly reduce the complexity of the manufacturing process and achieve the effect of lowering costs.

### FIELD OF THE INVENTION

The present invention relates to flip chip packages, more particularly to a flip chip packaging method and a flip chip assembly having a lead frame.

### BACKGROUND OF THE INVENTION

Flip chip packaging is an advanced semiconductor packaging technology, and the biggest difference between the semiconductor packaging of a flip chip package and a ball grid array (BGA) package resides on that the flip chip assembly installs a die surface upside down onto a lead frame (substrate) and electrically connects the chip with the lead frame by soldering a plurality of flip chip bumps. Since the flip chip package does not require a solder wire that occupies much space to provide an electric connection between the chip and the lead frame, therefore, the overall size of the packaged product can be reduced effectively.

In a prior art, it is necessary to produce a flip chip bump on a die surface of a chip to solder the chip onto a lead frame. Such manufacturing process is generally called the growth of solder balls, and the flip chip bump serves as a dielectric layer for electrically connecting the chip and the lead frame. In general, several manufacturing processes including film coating, reflow, steel plate printing, and rinsing are needed for producing the dielectric layer on the chip. Since the manufacturing process is complicated, the yield rate is low, and the cost is high, therefore the scope of applicability of the flip chip package is limited.

### SUMMARY OF THE INVENTION

The primary objective of the present invention is to overcome the foregoing shortcomings and avoid the existing deficiencies by providing a low-cost manufacturing process and method according to the present invention. The manufacturing process of the lead frame etches flip chip bumps.

Another objective of the present invention is to provide a flip chip assembly for simplifying the steps at a later section of the manufacturing process of the flip chip package.

In the present invention, a semi-etching method is used to produce a plurality of flip chip bumps on a lead frame having a plurality of flip chip areas, and produce a packaging chip having a plurality of bond pads; and a packaging material is injected into a package after a plurality of bond pads is electrically coupled to a plurality of flip chip bumps.

The flip chip assembly comprises a lead frame, having a flip chip area disposed at its surface; a plurality of flip chip bumps being disposed on the flip chip area of the lead frame, and the plurality of flip chip bumps being integrally coupled with the flip chip area; a metal layer formed by electroplating the surface of the plurality of flip chip bumps, and the plurality of bond pads is electrically connected to the plurality of the flip chip bumps, and a packaging material is filled between the chip and the lead frame to cover the chip.

### BRIEF DESCRIPTION OF THE DRAWINGS

FIG. 1 is a front view of the lead frame according to the present invention.

FIG. 2A is a flow chart of the first step of the semi-etching process according to the present invention.

FIG. 2B is a flow chart of the second step of the semi-etching process according to the present invention.

FIG. 2C is a flow chart of the third step of the semi-etching process according to the present invention.

FIG. 2D is a flow chart of the fourth step of the semi-etching process according to the present invention.

FIG. 3 is an illustrative view of the lead frame according to the present invention.

FIG. 4 is an illustrative view of combining a plurality of lead frames according to the present invention.

FIG. 5 is an illustrative view of the lead frame assembly according to the present invention.

FIG. 6 is an illustrative view of another lead frame assembly according to the present invention.

### DETAILED DESCRIPTION OF THE PREFERRED EMBODIMENTS

To make it easier for our examiner to understand the objective of the invention, its structure, innovative features, and performance, we use a preferred embodiment and the attached drawings for the detailed description of the invention.

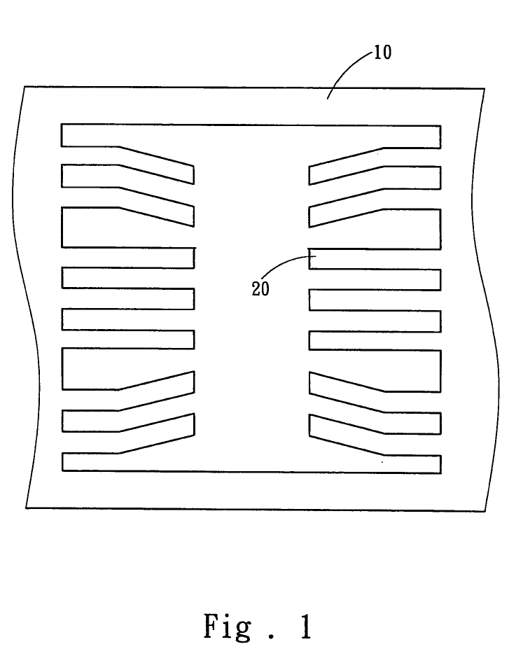

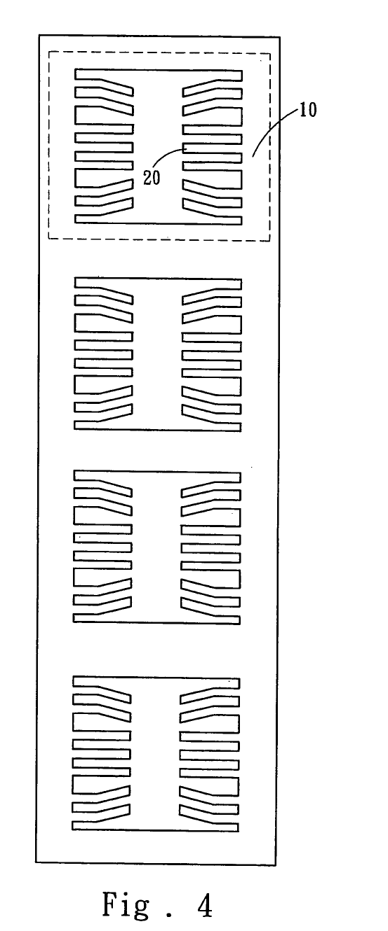

Please refer to FIG. 1 for the present invention. A lead frame 10 produced by etching comprises a plurality of flip chip areas 20 for connecting a bond pad 70 of a chip 80 as shown in FIG. 5.

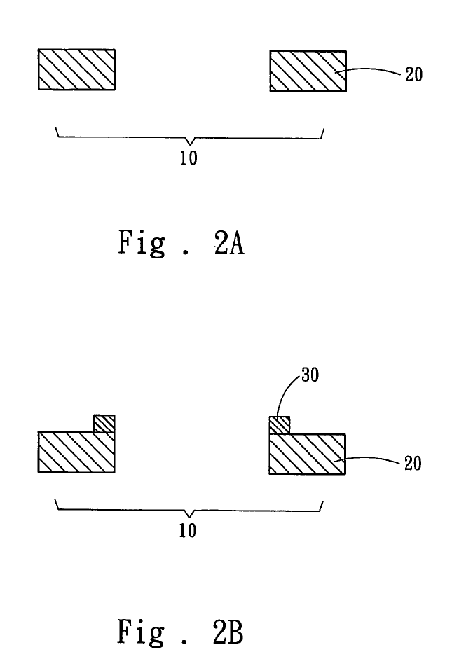

Please refer to FIGS. 2A to 2D for the illustrative flow of the semi-etching process. In FIG. 2A, a lead frame 10 having a plurality of flip chip areas 20 uses the lithographic method to produce a photoresist layer 30 onto a specific area in the flip chip area 20 as shown in FIG. 2B. An etching solution etches the exposed area of the photoresist layer of the flip chip area 20, and the etching time is controlled to form a rough surface on the flip chip area 20 having the flip chip bumps 40 as shown in FIG. 2C. Finally, the photoresist layer 30 is removed as shown in FIG. 2D to complete the semi-etching process according to the present invention, so that the lead frame 10 having the flip chip bumps 40 can be used for the flip chip packaging.

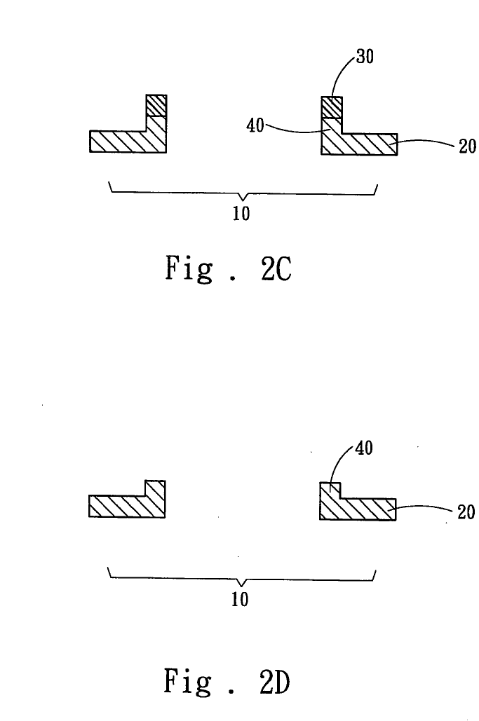

Please refer to FIG. 3 for the illustrative view of the lead frame according to the present invention. The lead frame 10 comprises a flip chip area 20 on its surface; a plurality of flip chip bumps 40 disposed on the flip chip area 20 of the lead frame 10, and the plurality of flip chip bumps 40 being integrally coupled with the flip chip area 20; a metal layer 60 produced by electroplating the surfaces of the plurality of flip chip bumps 40; wherein the metal layer 60 is made of gold, silver, or solder.

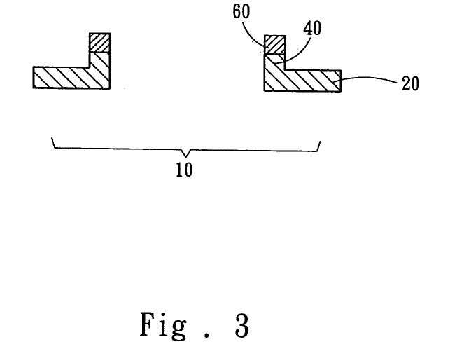

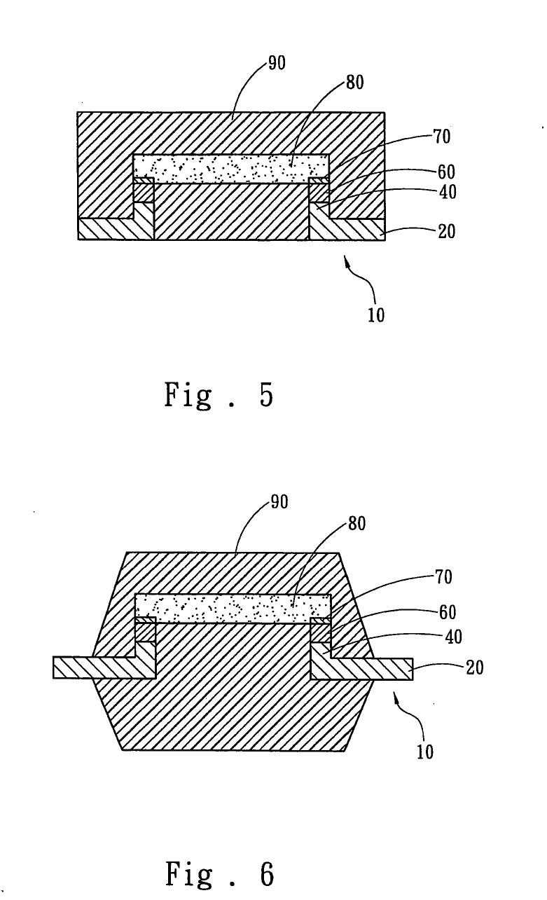

Please refer to FIG. 4 again. Several lead frames 10 are produced at the same time during the production of lead frames 10 to save production cost and maintain the beneficial results of the production, and the lead frames 10 are cut into individual packages after the packaging is completed. Please refer to FIGS. 5 and 6 again for the illustrative views of two different lead frame packaging assemblies. A packaging chip 80 having a plurality of bond pads 70 is produced. After the plurality of bond pads 70 and the plurality of flip chip bumps 40 are electrically connected, a packaging material 90 is injected to form the package. The difference between FIG. 5 and FIG. 6 resides on that the bottom of the packaging assembly as shown in FIG. 6 has the packaging material 90, and the flip chip area 20 (lead frame 10) is extended outward from the lateral side of the packaging assembly and connected to a circuit board (not shown in the figure) by a wire bonder. The package assembly as shown in FIG. 5 has its flip chip area 20 (lead frame 10) exposed directly on the bottom, and thus it can be connected directly to the circuit board (not shown in the figure). To give a better electric connection between the lead frame 10 and the chip 80, a metal layer 60 is electroplated onto the surfaces of the plurality of flip chip bumps 40 before the plurality of flip chip bumps 40 and the plurality of the bond pads 70 are electrically connected. Such metal layer 60 is generally made of a metal with good electrical properties for the soldering such as gold, silver, or solder. This manufacturing process can adopt the prior-art equipments for manufacturing the lead frame 10 in order to simplify the complexity of the manufacturing process of the lead frame 10. Such equipments are well developed and the cost relatively is low. Therefore, the present invention can effectively lower the overall manufacturing cost and also can extend the application of the flip chip packaging technology.

1. A flip chip packaging method, comprising the steps of:
using a semi-etching method to produce a plurality of flip chips on a lead frame having a plurality of flip chip areas;
producing a packaging chip having a plurality of bond pads; and
injecting a packaging material into a package after said plurality of bond pads being electrically coupled to a plurality of flip chip bumps.

2. The flip chip packaging method of claim 1, wherein said plurality of flip chip bumps have a metal layer electroplated onto their surfaces before electrically coupled with said plurality of bond pads.

3. The flip chip packaging method of claim 2, wherein said metal layer is made of gold.

4. The flip chip packaging method of claim 2, wherein said metal layer is made of silver.

5. The flip chip packaging method of claim 2, wherein said metal layer is made of solder.

6. The flip chip packaging method of claim 1, wherein said semi-etching method comprises the steps of using an etching solution to produce said plurality of flip chip bumps, forming a photoresist layer at a specific area in said flip chip area of said lead frame, controlling the time of contacting said etching solution with said flip chip area of said lead frame to produce a plurality of flip chip bumps, and removing said photoresist layer.

7. A flip chip assembly, comprising:
a lead frame, having a flip chip area disposed at a surface of said lead frame;
a plurality of flip chip bumps, said plurality of flip chip bumps being disposed on said flip chip area of said lead frame, said plurality of flip chip bumps being integrally coupled with said flip chip area;
a metal layer, said metal layer being disposed on a to surface of said plurality of flip chip bumps without covering an entire sidewall of said plurality of flip chip bumps.

8. The flip chip assembly of claim 7, wherein said metal layer is made of gold.

9. The flip chip assembly of claim 7, wherein said metal layer is made of silver.

10. The flip chip assembly of claim 7, wherein said metal layer is made of solder.

11. The flip chip assembly of claim 7, wherein said metal layer has a substantially rectangular shape.

12. The flip chip assembly of claim 11, wherein said flip chip area and said plurality of flip chip bumps form an L-shape.

13. The flip chip assembly of claim 12, wherein said metal layer is applied to a top end of the L-shape.

14. The flip chip assembly of claim 7, wherein said flip chip area and said plurality of flip chip bumps form an L-shape.

15. A flip chip assembly, comprising:
a lead frame, having a flip chip area disposed at a surface of said lead frame;
a plurality of flip chip bumps, said plurality of flip chip bumps being disposed on said flip chip area of said lead frame, said plurality of flip chip bumps being integrally coupled with said flip chip area, said flip chip area and said plurality of flip chip bumps forming a plurality of L-shaped structures;
a metal layer, said metal layer being disposed on a top surface of said plurality of flip chip bumps without covering an entire sidewall of said plurality of flip chip bumps, said metal layer being made of one of gold, silver and solder, said metal layer having a substantially rectangular shape.
